(19) United States
(12) Patent Application Publication
(10) Pub. No.: US 2014/0264886 A1
(43) Pub. Date: Sep. 18, 2014

(54) Forming Fence Conductors Using Spacer Pattern Transfer

(71) Applicant: MICROCHIP TECHNOLOGY INCORPORATED, Chandler, AZ (US)

(72) Inventor: Paul Fest, Chandler, AZ (US)

(73) Assignee: Microchip Technology Incorporated, Chandler, AZ (US)

(21) Appl. No.: 13/835,828

(22) Filed: Mar. 15, 2013

(51) Int. Cl. H01L 23/528; H01L 21/768

(52) U.S. Cl. CPC H01L 23/528; H01L 21/76895
USPC 257/770; 438/669; 257/773

(57) ABSTRACT

A spacer transfer process produces sub-lithographic patterns of conductive lines in a semiconductor die. A dielectric then a conductive material are deposited onto a face of a semiconductor substrate. A sacrificial dielectric is deposited on the conductive material and portions thereof are removed to form at least one trench comprising walls and a bottom exposing the conductive material. A hard mask is deposited over the sacrificial dielectric including the walls and bottom of the trench. Then the hard mask is removed therefrom except from the walls of the trench. Thereafter, the remaining sacrificial dielectric is removed leaving only the hard mask from the walls of the trench. Then all conductive material not protected by the remaining hard mask is removed. Thereafter, the hard mask is removed exposing a sub-lithographic pattern of fence conductors wherein portions thereof are removed at appropriate locations to produce desired conductor patterns comprising isolated fence conductors.

### TECHNICAL FIELD

The present disclosure relates to semiconductor integrated circuit (IC) fabrication, and more particularly, to forming sub-lithographic patterns of conductive lines in a semiconductor die (e.g., integrated circuit die) during fabrication thereof.

### BACKGROUND

Reduction in the size of patterned conductive lines used for interconnection of active elements, e.g., transistors, in a semiconductor die has been limited by the lithographic processes available. As the number of transistors have increased on the semiconductor die resulting from improvements in the lithographic masking processes forming these transistors, conductive lines that must interconnect these ever decreasing in size transistors have been unable to decrease proportionally in size with the smaller transistors.

### SUMMARY

Therefore, there is need for a way to decrease the size of patterned conductive lines without the limitations of the lithographic processes available for manufacturing semiconductor integrated circuits.

According to an embodiment, a method for forming fence conductors in a semiconductor integrated circuit die may comprise the steps of: depositing a dielectric on a face of a semiconductor substrate; depositing a conductive material on the dielectric; depositing a sacrificial dielectric on the conductive material; removing portions of the sacrificial dielectric to form at least one trench comprising walls and a bottom exposing the conductive material; depositing a hard mask over the remaining sacrificial dielectric including the vertical walls and bottom of the at least one trench; removing the hard mask from a top face of the sacrificial dielectric and the bottom of the at least one trench; removing the remaining sacrificial dielectric leaving only those portions of the hard mask that were on the walls of the at least one trench; removing the conductive material not covered by the remaining hard mask, wherein only thin conductive material remains between the remaining hard mask and the dielectric; and removing the remaining hard mask, wherein the thin conductive material may be exposed on the dielectric.

According to a further embodiment of the method, the portions of the thin conductive material exposed on the dielectric may be separated into independent fence conductors. According to a further embodiment of the method, after the step of removing the remaining sacrificial dielectric, may further comprise the step of removing portions of the hard mask where portions of the thin conductive material will separate into independent fence conductors.

According to a further embodiment of the method, the step of depositing the dielectric may comprise the step of depositing the dielectric to a thickness of from about 50 to about 5,000 nanometers on the face of the semiconductor substrate. According to a further embodiment of the method, the step of depositing the conductive material may comprise the step of depositing the conductive material to a thickness of from about 50 to about 5,000 nanometers on the dielectric. According to a further embodiment of the method, the step of depositing the sacrificial dielectric may comprise the step of depositing the sacrificial dielectric to a thickness of from about 100 to about 10,000 nanometers on the conductive material. According to a further embodiment of the method, the step of removing portions of the sacrificial dielectric to form at least one trench may comprise the step of removing portions of the sacrificial dielectric to form at least one trench having a width of from about 30 to about 10,000 nanometers. According to a further embodiment of the method, the hard mask deposited on the exposed surfaces of the remaining sacrificial dielectric, including the vertical walls and bottom of the at least one trench therein may have a thickness of from about 10 to about 5,000 nanometers.

According to a further embodiment of the method, the dielectric may comprise Silicon Dioxide. According to a further embodiment of the method, the conductive material may comprise aluminum. According to a further embodiment of the method, the conductive material may be selected from the group consisting of Titanium, Titanium Nitride, Tantalum, Tantalum Nitride, Silicon, Tungsten Silicide, and Cobalt Silicide. According to a further embodiment of the method, the step of separating portions of the thin conductive material may comprise the step of separating portions of the thin conductive material with reactive-ion etching (RIE). According to a further embodiment of the method, the RIE may be aggressive.

According to a further embodiment of the method, the step of separating portions of the conductive material may comprise the step of separating portions of the conductive material using via-like masks.

According to another embodiment, a semiconductor die may comprise: a semiconductor substrate; a dielectric over the semiconductor substrate; and at least one narrow line of conductive material on the dielectric. According to a further embodiment of the method, a plurality of fence conductors may be made by separating the at least two narrow lines of conductive material into desired lengths.

According to a further embodiment, the dielectric may have a thickness from about 50 to about 5,000 nanometers. According to a further embodiment, the at least one narrow line of conductive material may have a height from about 100 to about 10,000 nanometers. According to a further embodiment, the at least one narrow line of conductive material may have a thickness from about 30 to about 10,000 nanometers.

According to a further embodiment, the conductive material may comprise Aluminum. According to a further embodiment, the conductive material may comprise an aluminum alloy. According to a further embodiment, the conductive material may be selected from the group consisting of Titanium, Titanium Nitride, Tantalum, Tantalum Nitride, Silicon, Tungsten Silicide, and Cobalt Silicide.

### BRIEF DESCRIPTION OF THE DRAWINGS

A more complete understanding of the present disclosure may be acquired by referring to the following description taken in conjunction with the accompanying drawings wherein:

FIG. 1 illustrates a schematic plan view diagram of a semiconductor integrated circuit wafer comprising a plurality of semiconductor dice;

FIGS. 2, 3, 3A and 3B illustrate schematic elevational diagrams of semiconductor fabrication steps for forming sub-lithographic patterns of conductive lines in a semiconductor die, according to specific example embodiments of this disclosure;

FIG. 4 illustrates a schematic plan view diagram of a plurality of sub-lithographic patterns of conductive lines formed in a semiconductor die, according to a specific example embodiment of this disclosure;

FIG. 5 illustrates a schematic plan view diagram of a plurality of sub-lithographic patterns of conductive lines formed in a semiconductor die, according to a specific example embodiment of this disclosure;

FIG. 6 illustrates a schematic plan view diagram of the plurality of sub-lithographic patterns of conductive lines shown in FIG. 5 being prepared for separating the conductive lines from each other, according to a specific example embodiment of this disclosure;

FIG. 7 illustrates a schematic plan view diagram of the plurality of sub-lithographic patterns of conductive lines shown in FIGS. 5 and 6 with portions of the conductive lines removed to separate the conductive lines from each other, according to a specific example embodiment of this disclosure;

FIG. 8 illustrates a schematic plan view diagram of a plurality of sub-lithographic patterns of conductive lines having various routing paths that are formed in a semiconductor die, according to another specific example embodiment of this disclosure;

FIG. 9 illustrates a schematic plan view diagram of a plurality of sub-lithographic patterns of conductive lines having various routing paths as shown in FIG. 8 being prepared for separation into independent conductors in a semiconductor die, according to another specific example embodiment of this disclosure;

FIG. 10 illustrates a schematic plan view diagram of a plurality of sub-lithographic patterns of conductive lines having various routing paths as shown in FIGS. 8 and 9 after being separated into independent conductors in a semiconductor die, according to another specific example embodiment of this disclosure;

FIG. 11 illustrates a schematic process flow diagram for forming a plurality of sub-lithographic patterns of conductive lines in a semiconductor die, according to specific example embodiments of this disclosure; and

FIG. 12 illustrates a schematic process flow diagram for forming a plurality of sub-lithographic patterns of conductive lines in a semiconductor die, according to other specific example embodiments of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

According to the teachings of this disclosure, a spacer transfer process may be used to form sub-lithographic patterns of conductive lines in a semiconductor die. A dielectric may be deposited on a face of a semiconductor substrate. Then a conductive material may be deposited on the dielectric. A sacrificial dielectric may be deposited on the conductive material. Then portions of this sacrificial dielectric may be removed wherein at least one trench comprising walls and a bottom exposing the conductive material may be formed therein. A hard mask may be deposited over the sacrificial dielectric including the walls and bottom of the at least one trench. The hard mask may be removed from a top face of the sacrificial dielectric and the bottom of the at least one trench, wherein the hard mask remains on the walls of the at least one trench. Next the remaining sacrificial dielectric may be removed leaving only the hard mask that was on the walls of the at least one trench. It is contemplated and within the scope of this disclosure that separation of the fence conductors may be accomplished by selectively removing portions of the hard mask before the hard mask pattern is etched (transferred) onto the conductive material. Then all conductive material not covered (protected) by the remaining hard mask may be removed. Thereafter, the remaining hard mask may be removed exposing a sub-lithographic pattern of conductive lines, hereinafter “fence conductors,” formed from the remaining conductive material.

This sub-lithographic patterning of conductive lines to form fence conductors may be produced in a fabrication process that may be compatible with existing aluminum backend processing. If portions of the hard mask have not already been removed to subsequently separate the conductive material into fence conductors during transferring the hard mask pattern to the fence conductors, then portions of the fence conductors may be removed at appropriate locations (e.g., “broken”) to produce desired conductor patterns comprising the fence conductors. The conductive material deposition thickness helps in determining one dimension of the fence conductors, e.g., conductor height, and the thickness of the deposited hard mask substantially determines a second dimension, e.g., conductor width. Lengths of the fence conductors are determined by where the continuous fence conductors are “broken,” e.g., separated, disconnections made therebetween, etc., from each other.

Referring now to the drawings, the details of specific example embodiments are schematically illustrated. Like elements in the drawings will be represented by like numbers, and similar elements will be represented by like numbers with a different lower case letter suffix.

Referring to FIG. 1, depicted is a schematic plan view diagram of a semiconductor integrated circuit wafer comprising a plurality of semiconductor dice. A silicon wafer 102 may be scribed into a plurality of semiconductor dice 104 for further processing to create planar transistors, diodes and conductors on each of the plurality of semiconductor dice 104. After all circuits have been fabricated on the plurality of semiconductor dice 104, the dice 104 are singulated (separated) and packaged into integrated circuits (not shown).

Referring to FIGS. 2, 3, 3A and 3B, depicted are schematic elevational diagrams of semiconductor fabrication steps for forming sub-lithographic patterns of conductive lines in a semiconductor die, according to specific example embodiments of this disclosure. The first step (a) in forming fence conductors is shown in FIG. 2 wherein a dielectric 212 may be deposited on a surface of a semiconductor substrate 210 for each of the plurality of semiconductor dice 104. In step (b) a conductive material 218 may be deposited on the dielectric 212. In step (c) a sacrificial dielectric 222 may be deposited on the conductive material 218. In step (d) a portion of the sacrificial dielectric 222 may be selectively removed by, for example but not limited to, etching to form at least one trench 214 comprising walls 216 and a bottom exposing the conductive material 218.

In step (e) a hard mask 224 may be deposited over the exposed surfaces of the remaining sacrificial dielectric 222a and the vertical walls 116 and bottom of the at least one trench 214. In step (f) the hard mask 224 may be removed from a top face of the sacrificial dielectric 222a and the bottom of the at least one trench 214 by, for example but not limited to, etching. In step (g) the remaining sacrificial dielectric 222a may be removed by, for example but is not limited to, selective plasma etching or selective wet etching, leaving only the hard mask 224a that was on the walls 216 of the at least one trench 214.

It is contemplated and within the scope of this disclosure that separation of the fence conductors may be accomplished by selectively removing portions of the hard mask before the hard mask pattern is etched (transferred) onto the conductive material, instead of or in addition to post separation of the conductive material into fence conductors as more fully described herein.

In step (h) all conductive material 218 not covered (protected) by the remaining hard mask 224a may be removed, leaving only thin conductive material 218a remaining. In step (i) the remaining hard mask 224a may be removed, leaving only the remaining thin conductive material 218a, hereinafter “fence conductors.” The thickness of the deposited conductive material 218 may determine the height and the thickness of the deposited hard mask 224a on the walls 216 of the trench 214 may determine the thickness of the fence conductors 218a.

The conductive material 218 may be selected from many different types of conductive materials comprising metals, metal alloys, and non-metallic but conductive compounds that would be suitable for the conductive fences disclosed herein, as would be readily apparent to one having ordinary skill in the art of semiconductor integrated circuit fabrication and also having the benefit of this disclosure.

The dielectric 212 may be, for example but is not limited to, Silicon Dioxide. The conductive material 218 may be, for example but is not limited to, Aluminum, aluminum alloys, Titanium, Titanium Nitride, Tantalum, Tantalum Nitride, Silicon, Tungsten Silicide, Cobalt Silicide, etc. The sacrificial dielectric 222 may be, for example but is not limited to, Silicon Dioxide. The hard mask 224 may be, for example but is not limited to, Silicon Nitride.

The thickness of the layer of dielectric 212 may be from about 50 to about 5,000 nanometers. The thickness of the layer of conductive material 218 may be from about 50 to about 5,000 nanometers. The thickness of the layer of sacrificial dielectric 222 may be from about 100 to about 10,000 nanometers. The thickness of the layer of hard mask 224 may be from about 10 to about 5,000 nanometers. The depth of the at least one trench 214 may be from about 100 to about 10,000 nanometers. The width of the at least one trench 214 may be from about 30 to about 10,000 nanometers. The width or thickness of the fence conductors 218a may be from about 10 to about 5,000 nanometers.

Referring to FIGS. 4 and 5, depicted are schematic plan view diagrams of a plurality of sub-lithographic patterns of conductive lines formed in a semiconductor die, according to specific example embodiments of this disclosure. After removal of the continuous conductive material 218 down to where the tops of the fence conductors 218a are exposed as shown in FIGS. 3A and 3B step (i), the fence conductors 218a are ready for further processing. The fence conductors 218a may be separated in order to form useful independent circuit conductors. The plurality of fence conductors 218a shown in FIG. 5 may represent conductors used for a semiconductor transistor array. As mentioned hereinabove and more fully described hereinafter, separation of the fence conductors 218a may also be accomplished by selectively removing sections of the hard mask 224 before the hard mask pattern is etched (transferred) onto the conductive material 218.

Referring to FIG. 6, depicted is a schematic plan view diagram of the plurality of sub-lithographic patterns of conductive lines shown in FIG. 5 being prepared for separating the conductive lines from each other, according to a specific example embodiment of this disclosure. The ends of the of fence conductors 218a, represented by the numeral 620, are to be broken, e.g., separated apart, disconnections made therebetween, etc. The ends 620 may be routed to a “safe” area on the die 104 and may be “severed” (cut) with a removal process such as, for example is but not limited to, aggressive reactive-ion etching (RIE), where the ends 620 are exposed and the remainder of the plurality of fence conductors 218a are protected from the RIE, e.g., masked.

Referring to FIG. 7, depicted is a schematic plan view diagram of the plurality of sub-lithographic pattern with portions of the conductive lines removed to separate the conductive lines from each other, according to a specific example embodiment of this disclosure. The RIE mask may also be performed Via-like (small openings in the mask) to selectively break the fence conductors 218a at any place(s) on the semiconductor die 104.

Referring to FIG. 8, depicted is a schematic plan view diagram of a plurality of sub-lithographic patterns of conductive lines having various routing paths that are formed in a semiconductor die, according to another specific example embodiment of this disclosure. Fence conductors 218a as shown have been described more fully hereinabove. In is contemplated and with the scope of this disclosure that fence conductors 820 may be routed in as many different paths as desired and configured as conductors between active elements, e.g., transistors, on the semiconductor die 104. The steps for creating this pattern of fence conductors 820 are substantially the same as the process steps shown in FIGS. 2, 3, 3A and 3B, and the accompanying descriptions thereof as more fully described hereinabove.

Referring to FIG. 9, depicted is a schematic plan view diagram of a plurality of sub-lithographic patterns of conductive lines having various routing paths as shown in FIG. 8 being prepared for separation into independent conductors in a semiconductor die, according to another specific example embodiment of this disclosure. The fence conductors 820 may be separated, e.g., disconnections made therebetween, at various locations, generally represented by the numeral 822, on the semiconductor die 104. These separation locations 822 may be accomplished using Via style processes as is well known to those having ordinary skill in the art of semiconductor manufacturing and having the benefit of this disclosure.

Referring to FIG. 10, depicted is a schematic plan view diagram of a plurality of sub-lithographic patterns of conductive lines having various routing paths as shown in FIGS. 8 and 9 after being separated into independent conductors in a semiconductor die, according to another specific example embodiment of this disclosure. Then the fully separated fence conductors 1020 may be further connected to the active elements, e.g., transistors, and other connection nodes (not shown) in the semiconductor die 104.

Referring to FIG. 11, depicted is a schematic process flow diagram for forming a plurality of sub-lithographic patterns of conductive lines in a semiconductor die, according to specific example embodiments of this disclosure. In step 1102 a dielectric 212 may be deposited on a face of a semiconductor substrate (die) 210. In step 1104 a conductive material 218 may be deposited on the dielectric 212. In step 1106 a sacrificial dielectric 222 may be deposited on the conductive material 218. In step 1108 portions of the sacrificial dielectric 222 may be selectively removed to form at least one trench 214 comprising walls 216 and a bottom exposing the conductive material 218. In step 1110 a hard mask 224 may be deposited over the exposed surfaces of the remaining sacrificial dielectric 222a, the vertical walls 116 and bottom of the at least one trench 214. In step 1112 the hard mask 224 may be removed from a top face of the sacrificial dielectric 222a and the bottom of the at least one trench 214. In step 1114 the remaining sacrificial dielectric 222a may be removed leaving only the hard mask 224a that was on the walls 216 of the at least one trench 214. In step 1116 all conductive material 218 not covered (protected) by the remaining hard mask 224a may be removed, leaving only thin conductive material 218a remaining between the dielectric 212 and the hard mask 224a. In step 1118 the remaining hard mask 224a may be removed, leaving only the thin conductive material 218a. In step 1120 portions of the thin conductive material 218a may be separated, e.g., disconnections made therebetween, so as to create independent fence conductors 1020 therefrom that may be used to interconnect active devices (not shown) in the semiconductor die 104.

Referring to FIG. 12, depicted is a schematic process flow diagram for forming a plurality of sub-lithographic patterns of conductive lines in a semiconductor die, according to other specific example embodiments of this disclosure. In step 1102 a dielectric 212 may be deposited on a face of a semiconductor substrate (die) 210. In step 1104 a conductive material 218 may be deposited on the dielectric 212. In step 1106 a sacrificial dielectric 222 may be deposited on the conductive material 218. In step 1108 portions of the sacrificial dielectric 222 may be selectively removed to form at least one trench 214 comprising walls 216 and a bottom exposing the conductive material 218. In step 1110 a hard mask 224 may be deposited over the exposed surfaces of the remaining sacrificial dielectric 222a, the vertical walls 116 and bottom of the at least one trench 214. In step 1112 the hard mask 224 may be removed from a top face of the sacrificial dielectric 222a and the bottom of the at least one trench 214. In step 1114 the remaining sacrificial dielectric 222a may be removed leaving only the hard mask 224a that was on the walls 216 of the at least one trench 214. In step 1215 portions of the hard mask 224 may be removed where the conductive material 218 is to be separated into portions for creating independent fence conductors 1020 therefrom that may be used to interconnect active devices (not shown) in the semiconductor die 104. In step 1116 all conductive material 218 not covered (protected) by the remaining hard mask 224a may be removed, leaving only thin conductive material 218a remaining between the dielectric 212 and the hard mask 224a. In step 1118 the remaining hard mask 224a may be removed, leaving only the thin conductive material 218a.

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. A method for forming fence conductors in a semiconductor integrated circuit die, said method comprising the steps of:
depositing a dielectric on a face of a semiconductor substrate;
depositing a conductive material on the dielectric;
depositing a sacrificial dielectric on the conductive material;
removing portions of the sacrificial dielectric to form at least one trench comprising walls and a bottom exposing the conductive material;
depositing a hard mask over the remaining sacrificial dielectric including the vertical walls and bottom of the at least one trench;
removing the hard mask from a top face of the sacrificial dielectric and the bottom of the at least one trench;
removing the remaining sacrificial dielectric leaving only those portions of the hard mask that were on the walls of the at least one trench;
removing the conductive material not covered by the remaining hard mask, wherein only thin conductive material remains between the remaining hard mask and the dielectric; and
removing the remaining hard mask, wherein the thin conductive material is exposed on the dielectric.

2. The method according to claim 1, further comprising the step of separating portions of the thin conductive material exposed on the dielectric into independent fence conductors.

3. The method according to claim 1, wherein after the step of removing the remaining sacrificial dielectric, further comprising the step of removing portions of the hard mask where portions of the thin conductive material will separate into independent fence conductors.

4. The method according to claim 1, wherein the step of depositing the dielectric comprises the step of depositing the dielectric to a thickness of from about 50 to about 5,000 nanometers on the face of the semiconductor substrate.

5. The method according to claim 1, wherein the step of depositing the conductive material comprises the step of depositing the conductive material to a thickness of from about 50 to about 5,000 nanometers on the dielectric.

6. The method according to claim 1, wherein the step of depositing the sacrificial dielectric comprises the step of depositing the sacrificial dielectric to a thickness of from about 100 to about 10,000 nanometers on the conductive material.

7. The method according to claim 1, wherein the step of removing portions of the sacrificial dielectric to form at least one trench comprises the step of removing portions of the sacrificial dielectric to form at least one trench having a width of from about 30 to about 10,000 nanometers.

8. The method according to claim 1, wherein the hard mask deposited on the exposed surfaces of the remaining sacrificial dielectric, including the vertical walls and bottom of the at least one trench therein has a thickness of from about 10 to about 5,000 nanometers.

9. The method according to claim 1, wherein the dielectric comprises Silicon Dioxide.

10. The method according to claim 1, wherein the conductive material comprises aluminum.

11. The method according to claim 1, wherein the conductive material is selected from the group consisting of Titanium, Titanium Nitride, Tantalum, Tantalum Nitride, Silicon, Tungsten Silicide, and Cobalt Silicide.

12. The method according to claim 1, wherein the step of separating portions of the thin conductive material comprises the step of separating portions of the thin conductive material with reactive-ion etching (RIE).

13. The method according to claim 1, wherein the RIE is aggressive.

14. The method according to claim 1, wherein the step of separating portions of the conductive material comprises the step of separating portions of the conductive material using via-like masks.

15. A semiconductor die, comprising:
a semiconductor substrate;
a dielectric over the semiconductor substrate; and
at least one narrow line of conductive material on the dielectric.

16. The semiconductor die according to claim 15, further comprising a plurality of fence conductors made by separating the at least two narrow lines of conductive material into desired lengths.

17. The semiconductor die according to claim 15, wherein the dielectric has a thickness from about 50 to about 5,000 nanometers.

18. The semiconductor die according to claim 15, wherein the at least one narrow line of conductive material has a height from about 100 to about 10,000 nanometers.

19. The semiconductor die according to claim 15, wherein the at least one narrow line of conductive material has a thickness from about 30 to about 10,000 nanometers.

20. The semiconductor die according to claim 15, wherein the conductive material comprises Aluminum.

21. The semiconductor die according to claim 15, wherein the conductive material comprises an aluminum alloy.

22. The semiconductor die according to claim 15, wherein the conductive material is selected from the group consisting of Titanium, Titanium Nitride, Tantalum, Tantalum Nitride, Silicon, Tungsten Silicide, and Cobalt Silicide.
